(19) United States
(12) Patent Application Publication
(10) Pub. No.: US 2023/0200177 A1
(43) Pub. Date: Jun. 22, 2023

(54) DISPLAY PANEL

(71) Applicant: Hefei Visionox Technology Co., Ltd., Hefei (CN)

(72) Inventors: Min XU, Hefei (CN); Bo LI, Hefei (CN); Xisheng GUO, Hefei (CN); Jiarong XU, Hefei (CN); Kangcheng WU, Hefei (CN)

(73) Assignee: Hefei Visionox Technology Co., Ltd., Hefei (CN)

(21) Appl. No.: 18/169,413

(22) Filed: Feb. 15, 2023

Related U.S. Application Data
(63) Continuation of application No. PCT/CN2021/115164, filed on Aug. 27, 2021.

(30) Foreign Application Priority Data
Nov. 9, 2020 (CN) 202011239917.9

(51) Int. Cl. H10K 59/38; G06F 3/041; H10K 59/40; G09G 3/32

(52) U.S. Cl. CPC H10K 59/38; G06F 3/0412; G09G 3/32; H10K 59/40; G06F 2203/04111

(57) ABSTRACT

A display panel including an array substrate, a light emitting device layer, a touch plate and a color filter film layer. The light emitting device layer is arranged on the array substrate. The light emitting device layer includes a first electrode layer and an encapsulation layer arranged on a side of the first electrode layer away from the array substrate. The touch plate is positioned on a side of the encapsulation layer away from the array substrate. The touch plate includes a touch electrode layer. The color filter film layer is arranged between the touch electrode layer and the encapsulation layer to increase a dielectric spacing between the first electrode layer and the touch electrode layer.

### CROSS-REFERENCE TO RELATED APPLICATIONS

This application is a continuation of International Application No. PCT/CN2021/115164, filed on Aug. 27, 2021, which claims priority to Chinese Patent Application No. 202011239917.9, filed on Nov. 09, 2020, both of which are hereby incorporated by reference in their entireties.

### TECHNICAL FIELD

The present application relates to the technical field of display devices, and in particular to a display panel.

### BACKGROUND

Planar display panels, such as an organic light emitting display (OLED) panel and a display panel using light emitting diode (LED) devices, have been widely used in various consumer electronic products, such as mobile phones, televisions, personal digital assistants, digital cameras, laptop computers, desktop computers, due to their advantages of high image quality, power saving, thin body and wide range of applications, and have become the mainstream of display devices.

At present, the market pursues to develop thin and large-size display panels. However, the overall thickness of the display panel becoming thinner and the size of the display panel increasing will both easily cause the increase of parasitic capacitance between the functional layers, affect the application of functional layers such as touch plate, and also bring negative effects on the display effect of the display panel.

### SUMMARY

A display panel provided by the embodiments of the present application can, while realizing the thinning of the display panel, increase dielectric spacing between electrode layer in light emitting device layer and touch electrode layer in the display panel, reduce parasitic capacitance of the display panel, and ensure the smooth application of the touch plate in the display panel and a good display effect.

The display panel in the embodiments of the present application includes an array substrate, a light emitting device layer, a touch plate and a color filter film layer. The light emitting device layer is arranged on the array substrate, and the light emitting device layer includes a first electrode layer and an encapsulation layer arranged on a side of the first electrode layer away from the array substrate; the touch plate is positioned on a side of the encapsulation layer away from the array substrate, and the touch plate includes a touch electrode layer; the color filter film layer is arranged between the touch electrode layer and the encapsulation layer to increase a dielectric spacing between the first electrode layer and the touch electrode layer.

In the display panel provided by the embodiment of the present application, by arranging the color filter film layer between the touch electrode layer and the encapsulation layer, the dielectric spacing between the electrode layer in the light emitting device layer and the touch electrode layer is increased. In the case where the size of the display panel is unchanged, the parasitic capacitance between the electrode layer and the touch electrode layer can be reduced. The required capacitance load of an integrated circuit (IC) of the display panel is reduced, thereby ensuring desired display effect of the display panel. In addition, the reduction of the parasitic capacitance between the electrode layer and the touch electrode layer also increases the touch sensitivity of the touch plate in the display panel and improves the touch performance of the touch plate.

### BRIEF DESCRIPTION OF THE DRAWINGS

FIG. 1 is a schematic view of a layer structure of a display panel according to an embodiment of the present application.

FIG. 2 is a schematic view of a layer structure of another display panel according to an embodiment of the present application.

FIG. 3 is a schematic view of a layer structure of yet another display panel according to an embodiment of the present application.

FIG. 4 is a schematic view of a layer structure of still another display panel according to an embodiment of the present application.

### DETAILED DESCRIPTION

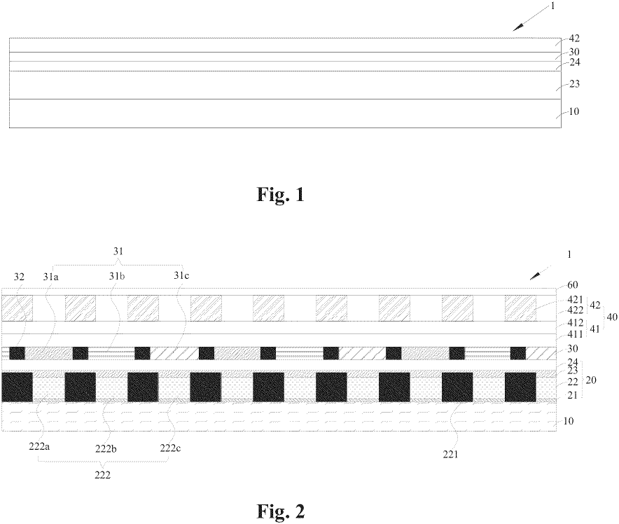

For a better understanding of the present application, a detailed description of a display panel according to an embodiment of the present application will be given below with reference to FIG. 1 to FIG. 4.

The inventors have found in intensive studies that, while constantly pursuing a thin body and a large size of a display panel, the overall thickness of the display panel becomes smaller. While the display panel becomes thinner, the dielectric spacing between a touch electrode in a touch panel and an electrode layer below an encapsulation layer of the display panel becomes smaller and the parasitic capacitance between the touch electrode and the electrode layer below the encapsulation layer of the display panel becomes larger. Therefore, when a user touches the display panel, the mutual capacitance value between a sensing electrode and a driving electrode arranged in the touch panel in the display panel decreases, resulting in a problem of poor sensitivity of the touch panel. While pursuing a big size of the display panel, according to C = εᵣ, * S/d (in the formula, C (Capacitance, C) represents the capacitance, εᵣ is the relative dielectric constant, S is the frontal area of the capacitor plate, and d is the distance between the capacitor plates), as the size of the display panel increases, S increases, and the parasitic capacitance C further increases, thus increasing the overall capacitive load of the IC in the display panel, thereby affecting the display effect of the display panel and also affecting the safety and reliability of the display panel during use. Generally, a parasitic capacitance can also be referred to as a stray capacitance. Due to the thin design of a display panel, a capacitance formed between an electrode layer, various circuit modules or electrical elements in the display panel and not in the design of the display panel is connected as a parasitic capacitance. Such parasitic capacitance, due to extreme instability, also affects the mutual capacitance value between the sensing electrode and the driving electrode arranged in the touch plate in the display panel, thereby generating a large interference to the working process of the display panel as a whole, thereby bringing a negative effect on the display effect of the display panel and the touch control performance of the touch plate in the display panel.

Furthermore, a flexible display panel is another hotspot of development in the technical field of display panels. However, a circular polarizer is generally arranged on a side of a light emitting surface of a display panel so as to avoid the reflection phenomenon generated when ambient light is incident on the display panel, thereby ensuring desired display effect. However, the thickness of the circular polarizer is large, and the thickness is generally on the order of several tens of micrometers to several hundreds of micrometers, which hinders the further thinning of the display panel to a certain extent. The circular polarizer has a strong brittleness and cannot be bent repeatedly, which makes it difficult to apply to a flexible and foldable display panel. Therefore, the inventors have made intensive studies to solve the above-mentioned problems of the general display panel, and have provided a novel display panel according to an embodiment of the present application.

Referring to FIG. 1, a display panel 1 of an embodiment of the present application includes an array substrate 10, a light emitting device layer, a color filter film layer 30 and a touch plate. The light emitting device layer is arranged on the array substrate 10. The light emitting device layer includes a first electrode layer 23 and an encapsulation layer 24 arranged on a side of the first electrode layer 23 away from the array substrate 10. The touch plate 40 is positioned on a side of the light emitting device layer 20 away from the array substrate 10. The touch plate includes a touch electrode layer 42. The touch plate 40 is positioned on a side of the encapsulation layer 24 away from the array substrate 10. The color filter film layer 30 is arranged between the touch electrode layer 42 and the encapsulation layer 24 to increase a dielectric spacing between the first electrode layer 23 and the touch electrode layer 42. The positional relationships between the array substrate 10, the first electrode layer 23, the encapsulation layer 24, the color filter film layer 30 and the touch electrode layer 42 in the display panel 1 of an embodiment of the present application are merely briefly illustrated in FIG. 1, and a plurality of functional layers are not shown, and FIG. 1 should not be understood as a schematic structural representation of all the functional layers of the display panel.

The display panel of an embodiment of the present application is provided with the color filter film layer 30 between the touch electrode layer 42 and the encapsulation layer 24, so that the dielectric spacing between the first electrode layer 23 in the light emitting device layer 20 and the touch electrode layer 42 is increased. In the case where the size of the display panel 1 is unchanged, the parasitic capacitance between the first electrode layer 23 and the touch electrode layer 42 can be reduced, reducing the required capacitance load of an integrated circuit (IC) in the display panel 1, thereby ensuring desired display effect of the display panel 1. Further, the reduction of the parasitic capacitance between the first electrode layer 23 in the light emitting device layer 20 and the touch electrode layer 42 also increases the touch sensitivity of the touch plate 40 in the display panel 1, improving the touch performance of the touch plate 40. In addition, the color filter film layer 30 can replace the function of a circular polarizer (not shown in the figures) generally provided on the light emitting surface of the display panel, so as to avoid the problem that the display effect is affected by the reflection phenomenon caused by ambient light incident on the display panel, and the thickness of the color filter film layer 30 being lower than the thickness of the circular polarizer can reduce the overall thickness of the display panel 1. Furthermore, the color filter film layer 30 is a flexible and rollable film layer, and replacement of the circular polarizer with the color filter film layer 30 enhances the foldability and bendability of the display panel 1.

Referring to FIG. 2, the touch plate 40 includes a base 41 arranged between the touch electrode layer 42 and the color filter film layer 30. The base 41 includes a buffer organic layer 411 and an insulation organic layer 412 that are stacked. The buffer organic layer 411 is arranged close to the color filter film layer so as to separate the touch electrode layer 42 in the touch plate from the encapsulation layer. The arrangement of the insulation organic layer 412 is beneficial to separate the touch electrode layer 42 in the touch plate from the array substrate 10, avoiding a short circuit due to contact between the touch electrode layer 42 and the array substrate 10 that are both metal layers, and ensuring the safety of the display panel 1 during use. The total thickness of both the buffer organic layer 411 and the insulation organic layer 412 ranges from 4 µm to 10 µm. The organic material used in the buffer organic layer 411 and the insulation organic layer 412 may be a polyimide-based resin, an epoxyimide-based resin, an epoxy-based resin, or the like. The base 41 of the touch plate 40 is formed of an organic material. The organic base 41 has a larger thickness and better flexibility and foldability than a general inorganic base 41. While the dielectric spacing between the first electrode layer 23 in the light emitting device layer 20 and the touch electrode layer 42 in the display panel 1 is further increased, the bending performance and the foldability of the display panel 1 can be greatly improved. While the capacitive load of the display panel IC is reduced and the display effect is improved, the foldability of the display panel 1 can be further ensured.

In some other embodiments, the touch plate includes a base arranged between the touch electrode layer and the color filter film layer. The base includes a buffer inorganic layer and an insulation inorganic layer that are stacked, and the buffer organic layer is arranged close to the color filter film layer.

As shown in FIG. 2, the touch electrode layer 42 includes a layer structure of a plurality of touch electrodes 421 and a plurality of light transmitting portions 422. In some embodiments, the display panel 1 further includes a planarization layer 60 arranged on a side of the touch electrode layer 42 away from the array substrate. The planarization layer 60 is a light-transmitting structural layer.

As shown in FIG. 2, the light emitting device layer 20 further includes a light emitting layer 22 and a second electrode layer 21. Along a thickness direction of the display panel 1, the first electrode layer 23 and the second electrode layer 21 are positioned on two opposite sides of the light emitting layer 22 respectively, and the second electrode layer 21 is positioned on a side of the first electrode layer 23 close to the array substrate 10. The first electrode layer 23 may be a cathode layer and the second electrode layer 21 may be an anode layer.

In some embodiments, the light emitting layer 22 in the display panel 1 further includes a pixel defining layer having a plurality of pixel openings arranged in an array and a definition object 221 arranged around the pixel openings. Light emitting units are arranged at the pixel openings, and light emitting units 222 of same color are arranged in one-to-one correspondence with light filter units 31 of same color. In some embodiments, the side of the light emitting unit 222 away from the array substrate 10 is at the same level as the side of the definition object 221 away from the array substrate 10 along the thickness direction of the pixel definition layer itself. In these embodiments, since the side of the light emitting unit 222 away from the array substrate 10 is at the same level as the side of the definition object 221 away from the array substrate 10, the flatness of the cathode layer in fabrication of the cathode layer by evaporation in the formation of the display panel can be ensured.

In some embodiments, the color filter film layer 30 includes a plurality of filter units 31 arranged in an array. The light emitting layer 22 includes light emitting units 222 arranged in one-to-one correspondence with the light filter units 31. In some embodiments, the color filter film layer 30 includes a plurality of filter units 31 of different colors arranged alternately.

As shown in FIG. 2, in some examples, the color filter film layer 30 includes a first color filter unit 31a, a second color filter unit 31b and a third color filter unit 31c arranged alternately. The first color filter unit 31a is arranged corresponding to the first color light emitting unit 222a, the second color filter unit 31b is arranged corresponding to the second color light emitting unit 222b, and the third color filter unit 31c is arranged corresponding to the third color light emitting unit 222c.

As shown in FIG. 2, in some embodiments, the color filter film layer 30 is a color filter. A plurality of filter units 31 in the color filter film layer 30 are arranged in one-to-one correspondence with the light emitting units 222, and a light shading structure 32 is provided between adjacent filter units 31.

In some examples, the light shielding structure 32 in the color filter film layer 30 is a black matrix. In these examples, first, the black matrix can avoid the light emitted from the filter unit 31 from being incident on light emission area of the light emitting display panel 1 corresponding to the adjacent filter unit 31, so as to avoid the phenomenon of color mixing between pixels in the display panel 1 and display color shift, and improve the color rendering accuracy and display precision of the display panel 1. Second, the arrangement of the black matrix can also absorb the ambient light which is incident on the display panel from outside, reduce the probability of reflection of external ambient light in the display panel 1, and improve the user’s viewing experience when using the display panel 1.

In some other examples, the light shielding structure 32 is formed by superimposing the edges of adjacent two of the filter units 31 that are of different colors. In an example, the first color filter unit 31a allows only red light to pass through, and the first color filter unit 31a is arranged corresponding to the first color light emitting unit 222a emitting red light. The second color filter unit 31b allows only green light to pass through, and the second color filter unit 31b is arranged corresponding to the second color light emitting unit 222b emitting green light. The first color filter unit 31a and the second color filter unit 31b are adjacent to each other. The part where the edges of the first color filter unit 31a and the second color filter unit 3 1b are superimposed has the filtering functions of the first color filter unit 31a and the second color filter unit 31b at the same time. That is, since the part where the edges of the first color filter unit 31a and the second color filter unit 31b are superimposed not only can filter out light other than red light but also can filter out light other than green light, the part can have equivalent effect to the shading and light absorption effects of a black matrix. It can not only prevent the phenomenon of mixing of light of different colors between adjacent pixels, but also can absorb ambient light, which avoids the reflection of ambient light in the display panel, and further improves the display effect.

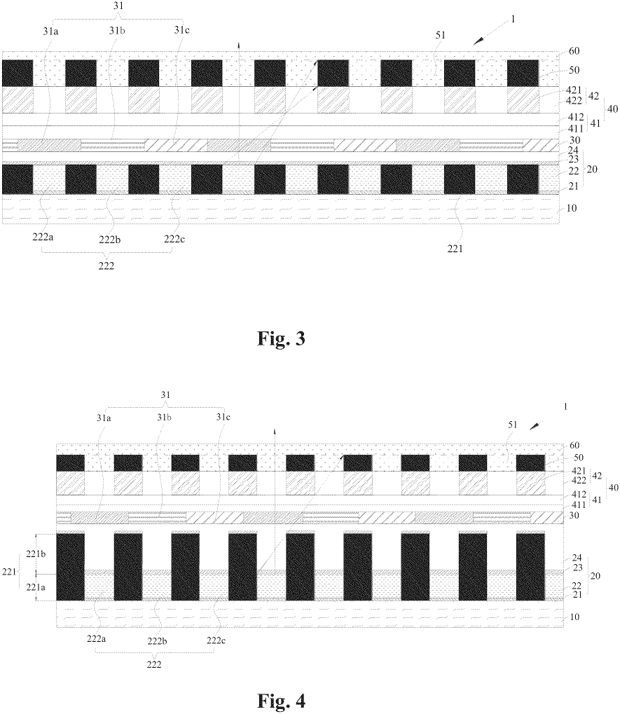

In some optional embodiments, please see FIG. 3, the illustrated structure is different from the layer structure of the display panel shown in FIG. 2 in that: the color filter film layer 30 in the display panel 1 includes a color filter film structure layer body of a plurality of filter units 31 arranged in an array. In some embodiments, the display panel 1 further includes a light barrier layer having a plurality of openings. The light barrier layer includes a plurality of openings 51 and a barrier 50 arranged around the openings 51. The light barrier layer is arranged on the side of the touch electrode layer 42 away from the array substrate 10, and the touch electrode layer 42 includes a plurality of touch electrodes 421 and a plurality of light transmitting portions 422. In some examples, the plurality of touch electrodes 421 cross each other to form a metal mesh structure. The metal mesh structure formed by the touch electrodes 421 is arranged corresponding to the definition object 221, and the light transmitting portions 422 are arranged corresponding to the light emitting units 222. The barrier 50 in the light barrier layer covers the touch electrode layer 42, and the light transmitting portions 422 are exposed through the openings 51 of the light barrier layer. In some examples, the light barrier layer is a black matrix structure layer, that is, the barrier 50 is a black matrix. The barrier 50 can absorb light which exit from the display panel 1 and meet a certain exit relationship, so as to prevent the problem of color mixing of emitted light between light emitting units when the display panel functions for displaying, and can also absorb ambient light which is incident on the display panel, so as to prevent the display effect from being affected by the ambient light when it exits the display panel after being reflected in the display panel after being incident on the interior of the display panel.

In the above-mentioned embodiments, the color filter film layer 30 may replace the functionality of the circular polarizer, so as to prevent ambient light from reflecting out of the display panel 1 via the reflective material, such as a metal material, arranged in the display panel 1 after ambient light is incident on the interior of the display panel 1. The reason is that, when ambient light incident on the interior of the display panel 1 continues to enter the interior of the display panel 1 through the color filter film layer 30, each filter unit 31 can only allow light of a single color to pass through and filter out and absorb light of other colors, so that most of the light is filtered out by the color filter film layer 30 during ambient light incident on the interior of the display panel 1. When a small portion of the light entering the display panel 1 is reflected inside the display panel 1 and exits the display panel, it will meet the color filter film layer 30 again. When the reflected light is incident on the filter unit 31 of different color, the filter unit 31 of different color will absorb and filter out the reflected light, further reducing the light intensity of the reflected light which can finally exit the display panel 1, and thus the color filter film layer 30 can replace the functionality of the circular polarizer. Therefore, the display panel 1 in the embodiments of the present application does not need to be provided with a circular polarizer to prevent the reflection of ambient light.

Furthermore, the thickness of the circular polarizer is generally on the order of several tens of microns to several hundreds of microns, while the thickness of the color filter film layer 30 in the embodiments of the present application ranges from 0 microns to 10 microns, which does not include the case where the thickness of the color filter film layer 30 is 0 microns. Therefore, the overall thickness of the display panel 1 can be greatly reduced, and the general components for manufacturing the filter unit 31 are organic materials such as a photocurable resin, an alkali soluble resin and a photoinitiator. Thus, the color filter film layer 30 has flexibility and bendability, so as to further ensure the bendability of the display panel 1 and enable the display panel 1 to have bendable and foldable properties. In an embodiment of the present application, the color filter film layer 30 is arranged between the touch electrode layer 42 and the encapsulation layer 24, and the color filter film layer 30 is an insulator, so that the dielectric spacing between the first electrode layer 23 and the touch electrode layer 421 increases, namely, d in C = εᵣ * S/d increases. Therefore, in the case where the size of the display panel 1 is unchanged, namely, the area S is unchanged, the parasitic capacitance between the electrode layer (including the first electrode layer 23 and the second electrode layer 21) in the light emitting device layer 20 and the touch electrode layer 132 decreases, reducing the capacitance load of the display panel IC. While the safe and stable operation of the display panel 1 is ensured, the display effect of the display panel 1 and the touch control performance of the touch plate 40 in the display panel 1 is improved, which brings a good use experience for a user.

In some optional embodiments, when the base of the touch plate includes a buffer inorganic layer and an insulation organic layer, the main reason for the increased dielectric spacing between the first electrode layer 23 and the touch electrode layer 42 is that the color filter film layer 30 is provided in the display panel. In these embodiments, the dielectric spacing between the first electrode layer 23 and the touch electrode layer is increased by dl, 0 µm <dl ≤ 10 µm.

In other optional embodiments, when the base of the touch plate includes the buffer organic layer 411 and the insulation organic layer 412, the total thickness of both the buffer organic layer 411 and the insulation organic layer 412 ranges from 4 µm to 10 µm. Then, the main reason for the increased dielectric spacing between the first electrode layer 23 and the touch electrode layer 42 is that the color filter film layer 30, the buffer organic layer 411 and the insulation organic layer 412 are provided in the display panel. The dielectric spacing between the first electrode layer 23 and the touch electrode layer in the display panel is increased by d2, 4 µm ≤ d2 ≤ 20 µm.

In other examples, the touch plate further includes a first planarization layer on a side of the touch electrode layer away from the array substrate. The above-mentioned light barrier layer is provided on the side of the first planarization layer away from the array substrate. The display panel further includes a second planarization layer arranged on an upper side of the light barrier layer, that is, in this example, the second planarization layer is arranged at the plurality of openings in the light barrier layer and covers a side surface of the light barrier layer away from the array substrate.

In other examples, as shown in FIG. 3, the touch plate 40 and the light barrier layer in the display panel 1 share a planarization layer 60, which is arranged at the plurality of openings in the light barrier layer and covers a side surface of the barrier 50 away from the array substrate 10. Further, the light barrier layer is arranged in contact with the touch electrode layer, that is, the barrier 50 is arranged in contact with the touch electrode 421, and the light transmitting portions 422 of the planarization layer 60 exposed through the openings 51 of the light barrier layer are arranged in contact. In these examples, the planarization layer 60 is a light-transmitting structure layer. By sharing a planarization layer 60 between the touch plate 40 and the light barrier layer, the function of providing protection and planarization for the touch electrode layer 42 and the light barrier layer can be realized. In addition, the process of providing a further protective layer on the side of the touch electrode layer 42 away from the array substrate 40 can be simplified, which further contributes to the overall thinning design of the display panel 1 and avoids increasing the overall thickness of the display panel 1.

As shown in FIG. 3, along the thickness direction of the display panel 1, the thickness of the light barrier layer 50 is arranged according to a certain relationship. Light emitted from the light emitting unit 222 can exit the display panel 1 only through the opening 51 of the light barrier layer 50 corresponding to the light emitting unit 222. The light barrier layer 50 absorbs light which enters the opening 51 of the light barrier layer 50 from the light emitting layer 22 and emits light with a color inconsistent with that of the light emitting unit corresponding to the opening 51 of the light barrier layer 50.

As shown in FIG. 3, the pixel definition layer in the display panel 1 has a plurality of pixel openings arranged in an array and a definition object 221 arranged around the pixel openings. The light emitting units 222 are arranged at the pixel openings, and the light emitting units 222 of same color are arranged in one-to-one correspondence with the light filter units 31 of same color to form a plurality of light emission channels. The color filter film layer 30 includes a first color filter unit 31a, a second color filter unit 31b and a third color filter unit 31c that are alternately arranged. The first color filter unit 31a is arranged corresponding to the first color light emitting unit 222a, and the first color light emitting unit 222a emits red light. The first color filter unit 31a and the first color light emitting unit 222a correspondingly form a red light emission channel. The second color filter unit 3 1b is arranged corresponding to the second color light emitting unit 222b, and the second color light emitting unit emits green light. The second color filter unit 3 1b and the second color light emitting unit 222b correspondingly form a green light emission channel. The third color filter unit 31c is arranged corresponding to the third color light emitting unit 222c, and the third color light emitting unit 222c emits blue light. The third color filter unit 31c and the third color light emitting unit 222c correspondingly form a blue light emitting channel. The shape of the light emitting unit 22 may be various shapes such as a rectangle, a circle, or an ellipse.

Along the thickness direction of the display panel 1, the light transmitting portions 422 of the touch electrode layer 42 are in one-to-one correspondence with the openings 51 of the light barrier layer, to form a plurality of light transmission channels. In each sub-pixel of the display panel 1, the light emission channel corresponds to the light transmission channel. It should be noted that a sub-pixel of the display panel 1 refers to the minimum display unit for realizing actual light emitting display on the display surface of the display panel with respect to the overall display panel, and each sub-pixel corresponds to one light emitting unit. In some examples, the sub-pixels include: a red sub-pixel emitting red light, a green sub-pixel emitting green light, and a blue sub-pixel emitting blue light. The light emitted by the light emitting unit 222 needs to pass through the corresponding filter unit 31 and then exits from the filter unit 31, and therefore the light emitting unit 222 and the filter unit 31 of the same color in the display panel correspondingly form a light emission channel of a sub-pixel.

In the display panel 1, thicknesses of the light-emitting device layer 20, the color filter film layer 30, the touch plate 40 and the barrier 50, and an arrangement of the light emission channels and the light transmission channels satisfy the following relationship:

in the sub-pixel, for light emitted via a first one of the light emission channels, a part of the light is emitted outside through the first one of the light transmission channels of the sub-pixel, and the other part of the light enters a second one of the light transmission channels of an adjacent sub-pixel and is totally absorbed by the barrier surrounding the second one of the light transmission channels.

It needs to be stated that a plurality of sub-pixels are arranged in a pre-set manner in a display panel. For clarity of description herein, a first sub-pixel is used to represent a certain sub-pixel of a plurality of sub-pixels in a display panel, and the first sub-pixel having a first light emission channel. With reference to the first sub-pixel, sub-pixels adjacent to the first sub-pixel are all referred to as second sub-pixels, and the second sub-pixel has a second light transmission channel. That is, in an embodiment of the present application, the first sub-pixel and the second sub-pixel are used to distinguish a certain sub-pixel and an adjacent sub-pixel in a display panel.

In some examples, as shown in FIG. 3, the sub-pixel corresponding to the first color light emitting unit 222a is taken as the first sub-pixel. It can be seen from FIG. 3 that, in the display panel in this example, in the first sub-pixel, for red light emitted via a first light emission channel, a part of the red light is emitted outside through the first light transmission channel of the first sub-pixel, and the other part of the red light enters a second light transmission channel of an adjacent sub-pixel and is totally absorbed by the barrier surrounding the second light transmission channel. In this example, the second sub-pixel corresponds to the second color light emitting unit 222b, and the second sub-pixel emits green light. The second color light emitting unit 222b is arranged adjacent to the first color light emitting unit 222a. In the second light transmission channel, the other part of the red light at the light transmitting portion 422 corresponding to the touch electrode layer 42 is not reflected on the touch electrode 421, so as to avoid that the thickness of the barrier 50 in the barrier layer needs to be increased so that the reflection of the other part of the red light at the light transmitting portion 422 corresponding to the touch electrode layer 42 on the touch electrode 421 is completely absorbed. While the increase in the overall thickness of the display panel 1 is avoided, the red light and the green light exit the display panel from the second light transmission channel corresponding to the second sub-pixel after color mixing, which results in the problem of display color mixing and low color rendering accuracy of the display panel, is avoided. Therefore, the accuracy of the color rendering of the display panel is improved, and the display effect of the display panel is improved, which improves the user experience.

With particular reference to FIG. 4, along the thickness direction of the pixel definition layer itself, the definition object 221 includes a body portion 221a and a light blocking portion 221b formed by extending a side of the body portion 221a away from the array substrate 10, and the light blocking portion 221b protrudes from the light emitting units 222 along the thickness direction of the pixel definition layer itself. In these embodiments, the display panel is the same as the embodiment shown in FIG. 3 except that the structure of the definition object 221 is different from that of the embodiment shown in FIG. 3, and the description thereof will not be repeated.

In these embodiments, in the display panel, thicknesses of the light-emitting device layer 20, the color filter film layer 30, the touch plate 40 and the barrier 50, and an arrangement of the light emission channels and the light transmission channels satisfy the following relationship:

in the sub-pixel, for light emitted via a first light emission channel, a part of the light is emitted outside through the first light transmission channel of the sub-pixel, and the other part of the light enters a second light transmission channel of an adjacent sub-pixel and is totally absorbed by the barrier surrounding the second light transmission channel.

As shown in FIG. 4, in some embodiments, the sub-pixel corresponding to the first color light emitting unit 222a is the first sub-pixel. In these embodiments, the light blocking portion 221b protrudes from the first color light emitting unit 222a. The light blocking portion 221b can direct the light emitted by the first color light emitting unit 222a to exit the display panel 1 more concentratedly from the first light transmission channel, and ensure that all of the other part of the light emitted by the first color light emitting unit 222a entering the second light transmission channel is absorbed by the barrier 50 surrounding the second light transmission channel while the thickness of the barrier 50 in the light barrier layer is further reduced. The color rendering accuracy in the display panel 1 is ensured while desired sub-pixel display brightness is ensured, and the thinning design of the display panel 1 as a whole is further achieved. The arrangement of the light blocking portion 221b further increases the dielectric spacing between the first electrode layer 23 and the touch electrode layer 42, which further improves the touch performance of the touch plate 40 in the display panel 1 and reduces the capacitive load of the display panel IC. In these embodiments, the other part of the red light entering the second light transmission channel of the adjacent second sub-pixel is not reflected on the touch electrode 421 at the light transmitting portion 422 of the touch electrode layer 42 in the second light transmission channel. It is avoided that the barrier 50 in the barrier layer requires an increased thickness to fully absorb the reflected light generated by the red light at the touch electrode 421 in the second light transmission channel. While the increase in the overall thickness of the display panel 1 is avoided, the red light and the green light exit the display panel 1 from the second light transmission channel corresponding to the second sub-pixel after color mixing, which results in the problem of display color mixing and low color rendering accuracy of the display panel, is avoided. Therefore, the accuracy of the color rendering of the display panel is improved, and the display effect of the display panel is improved, which improves the user experience.

What is claimed is:

1. A display panel, comprising:
an array substrate;
a light emitting device layer arranged on the array substrate, the light emitting device layer comprising a first electrode layer and an encapsulation layer arranged on a side of the first electrode layer away from the array substrate;
a touch plate positioned on a side of the encapsulation layer away from the array substrate, the touch plate comprising a touch electrode layer;
a color filter film layer arranged between the touch electrode layer and the encapsulation layer to increase a dielectric spacing between the first electrode layer and the touch electrode layer.

2. The display panel according to claim 1, wherein the touch plate comprises a base arranged between the touch electrode layer and the color filter film layer, the base comprises a buffer organic layer and an insulation organic layer that are stacked, and the buffer organic layer is arranged close to the color filter film layer.

3. The display panel according to claim 1, wherein the touch plate comprises a base arranged between the touch electrode layer and the color filter film layer, the base comprises a buffer inorganic layer and an insulation inorganic layer that are stacked, and the buffer inorganic layer is arranged close to the color filter film layer.

4. The display panel according to claim 1, wherein the light emitting device layer further comprises a light emitting layer and a second electrode layer, the first electrode layer and the second electrode layer are positioned on two opposite sides of the light emitting layer respectively along a thickness direction of the display panel, and the second electrode layer is positioned on a side of the first electrode layer close to the array substrate.

5. The display panel according to claim 4, wherein the color filter film layer comprises a plurality of filter units distributed in an array, and the light emitting layer comprises light emitting units arranged in one-to-one correspondence with the filter units.

6. The display panel according to claim 5, wherein the color filter film layer further comprises a light shielding structure positioned between adjacent ones of the filter units.

7. The display panel according to claim 6, wherein the light shielding structure is a black matrix, or the light shielding structure is formed by superimposing edges of adj acent two of the filter units that are of different colors.

8. The display panel according to claim 4, wherein
the color filter film layer comprises a plurality of filter units of different colors arranged alternately;
the display panel further comprises a light barrier layer arranged on a side of the touch electrode layer away from the array substrate, the light barrier layer includes a plurality of openings and a barrier arranged around the openings, the touch electrode layer comprises a plurality of touch electrodes and a plurality of light transmitting portions, the barrier covers the touch electrodes, and the light transmitting portions are exposed through the openings.

9. The display panel according to claim 8, wherein the barrier is a black matrix.

10. The display panel according to claim 8, further comprising a planarization layer arranged at the plurality of openings and covering a side surface of the barrier away from the array substrate.

11. The display panel according to claim 10, wherein the light barrier layer is arranged in contact with the touch electrode layer, and the light transmitting portions are exposed from the openings and in contact with the planarization layer.

12. The display panel according to claim 4, further comprising a planarization layer, the planarization layer being arranged on a side of the touch electrode layer away from the array substrate, and the planarization layer being a light-transmitting structure layer.

13. The display panel according to claim 8, wherein the light emitting layer further comprises a pixel definition layer, the pixel definition layer includes a plurality of pixel openings arranged in an array and a definition object arranged around the pixel openings, the light emitting units are arranged at the pixel openings, and ones of the light emitting units of same color are arranged in one-to-one correspondence with ones of the light filter units of same color to form a plurality of light emission channels.

14. The display panel according to claim 13, wherein the definition object includes a body portion and a light blocking portion formed by extending a side of the body portion away from the array substrate, and the light blocking portion protrudes from the light emitting units along a thickness direction of the pixel definition layer.

15. The display panel according to claim 13, wherein the plurality of touch electrodes cross each other to form a metal mesh structure, the metal mesh structure formed by the plurality of touch electrodes is arranged corresponding to the definition object, and the light transmitting portions are arranged corresponding to the light emitting units.

16. The display panel according to claim 4, wherein the light emitting layer further comprises a pixel definition layer, the pixel definition layer includes a plurality of pixel openings arranged in an array and a definition object arranged around the pixel openings, the light emitting units are arranged at the pixel openings, and ones of the light emitting units of same color are arranged in one-to-one correspondence with ones of the light filter units of same color to form a plurality of light emission channels.

17. The display panel according to claim 13, wherein along the thickness direction of the display panel, the light transmitting portions of the touch electrode layer are in one-to-one correspondence with the openings of the light barrier layer to form a plurality of light transmission channels, and in each sub-pixel of the display panel, the light emission channel corresponds to the light transmission channel.

18. The display panel according to claim 17, wherein in the display panel, thicknesses of the light emitting device layer, the color filter film layer, the touch plate and the barrier, and an arrangement of the light emission channels and the light transmission channels satisfy the following relationship:
in each sub-pixel, for light emitted via a first one of the light emission channels, a part of the light is emitted outside through the first one of the light transmission channels of the sub-pixel, and the other part of the light enters a second one of the light transmission channels of an adjacent sub-pixel and is totally absorbed by the barrier surrounding the second one of the light transmission channels.
